(19) United States
(12) Patent Application Publication
(10) Pub. No.: US 2025/0287615 A1
(43) Pub. Date: Sep. 11, 2025

(54) ELECTRONIC COMPONENT AND MANUFACTURING METHOD THEREOF

(71) Applicant: Taiwan Semiconductor Manufacturing Company, Ltd., Hsinchu (TW)

(72) Inventors: Po Chun CHANG, New Taipei City (TW); Hsuan-Han Tseng, Tainan City (TW); Kun-Hui Lin, Tainan City (TW); Kuo-Cheng Lee, Tainan City (TW)

(73) Assignee: Taiwan Semiconductor Manufacturing Company, Ltd., Hsinchu (TW)

(21) Appl. No.: 18/597,846

(22) Filed: Mar. 6, 2024

(51) Int. Cl. H01L 27/12; H01L 27/146

(52) U.S. Cl. CPC H10D 1/042; H10D 1/714; H10D 1/716; H10D 86/481; H10D 86/60; H10F 39/809

(57) ABSTRACT

A structure including a metal-insulator-metal (MIM) capacitor is provided. The MIM capacitor includes a second electrode, a dielectric layer, a first electrode. The second electrode has a main portion, at least one branch portion extending from the main portion, and a plurality of twig portions, extending from the branch portion. The dielectric layer covers a lower surface of the main portion, and extends for completely covering outer surfaces of the branch portion and twig portions of the second electrode. The first electrode conformally covers the dielectric layer, wherein the first electrode and second electrode are physically and electrically separated by the dielectric layer.

### BACKGROUND

Modern day integrated chips include various active devices and/or passive devices. Metal-insulator-metal (MIM) capacitors are a common type of passive device that is often integrated into the integrated chips. For example, the capacitor may be used in various radio frequency (RF) circuits (e.g., an oscillator, phase-shift network, filter, converter, etc.), memory devices, and as a decoupling capacitor in high power microprocessor units (MPUs).

Therefore, it is desirable to provide a MIM capacitor or a manufacturing method thereof with a large capacitance and a small chip area requirement.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1I illustrate various cross-sectional views of some embodiments of a method of forming an electronic component.

FIG. 1J illustrates a cross-sectional view of some embodiments of an electronic component.

FIG. 1K illustrates a top view of some embodiments of an electronic component.

FIG. 2 illustrates a various cross-sectional view of some embodiments of an electronic component.

FIG. 3 illustrates a various cross-sectional view of some embodiments of an electronic component.

FIG. 4 illustrates a various cross-sectional view of some embodiments of an electronic component.

FIG. 5 illustrates a various cross-sectional view of some embodiments of an electronic component.

FIG. 6 illustrates a flow diagram of some embodiments of a method of forming an electronic component.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

It will be understood that, although the terms “first”, “second”, “third” and the like, may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

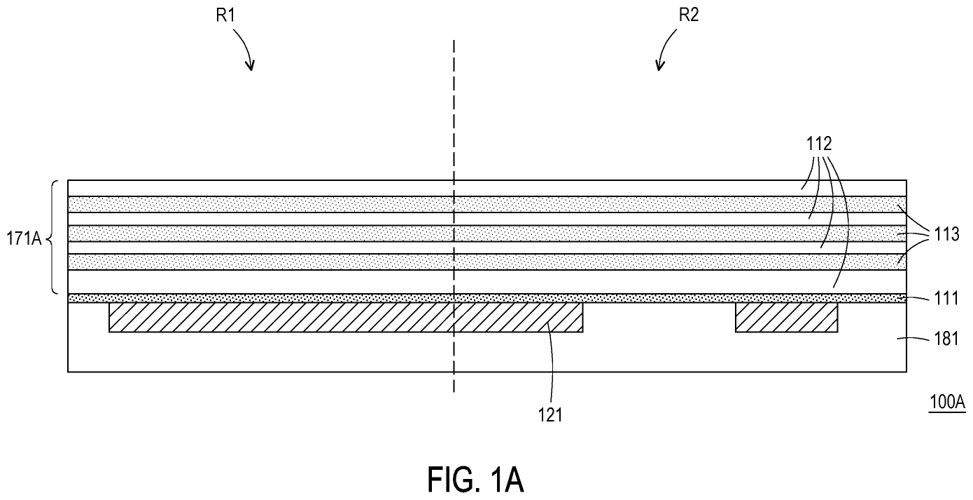

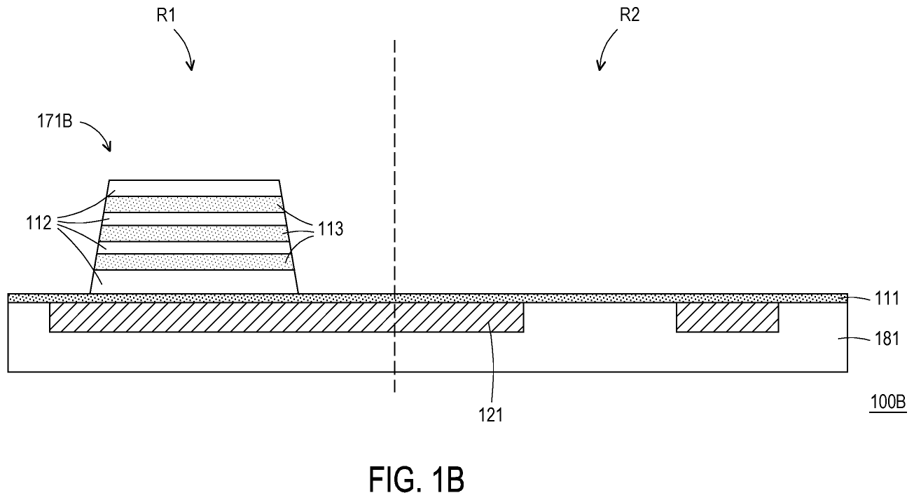

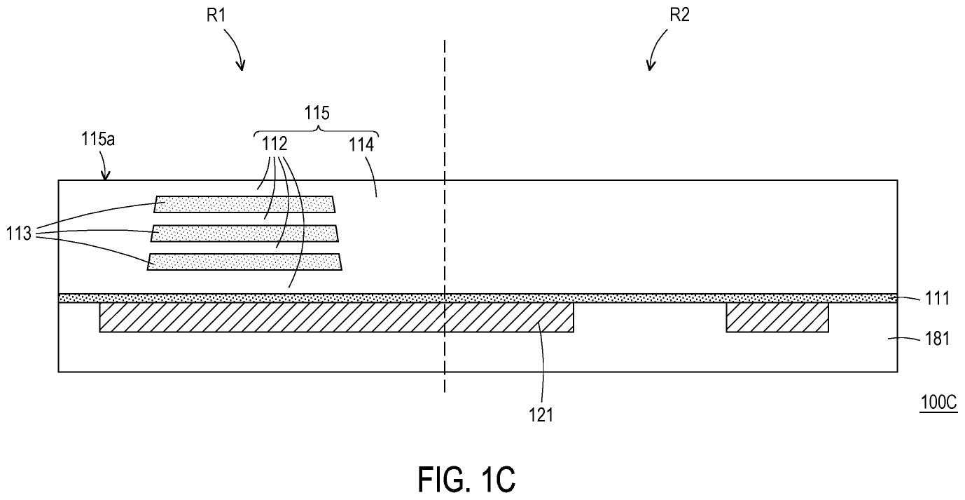

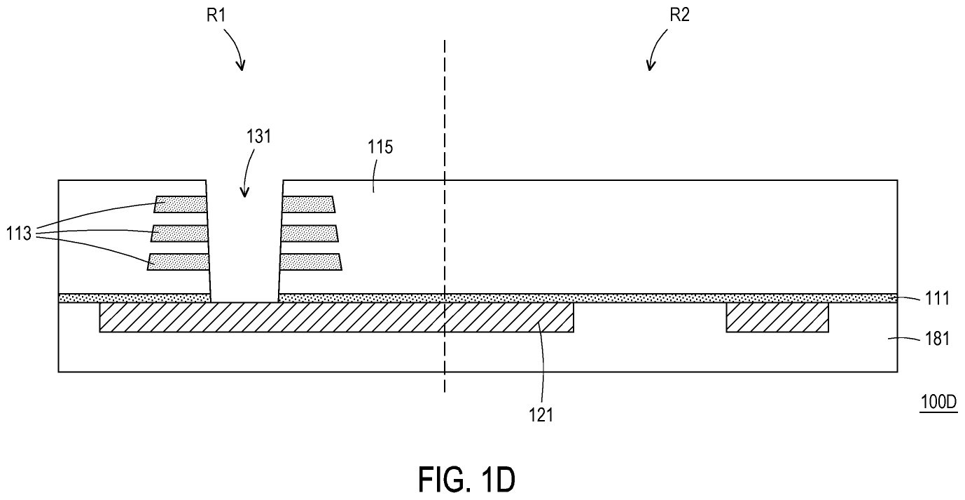

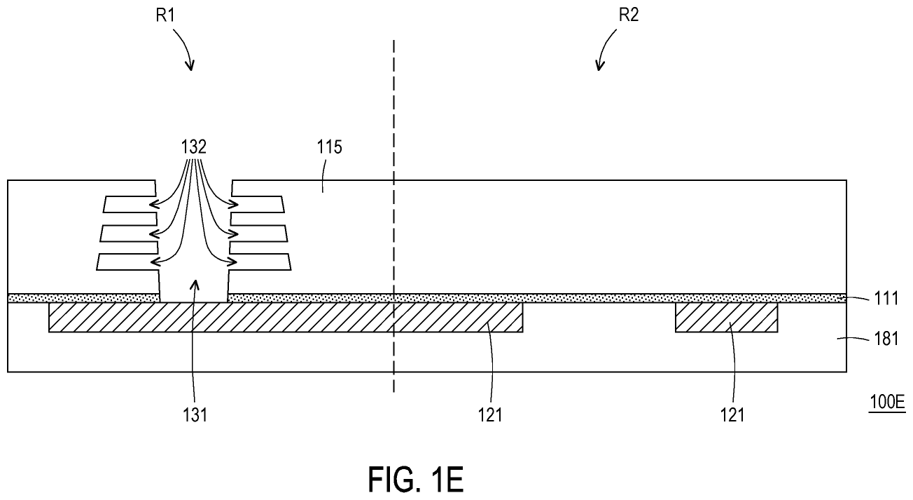

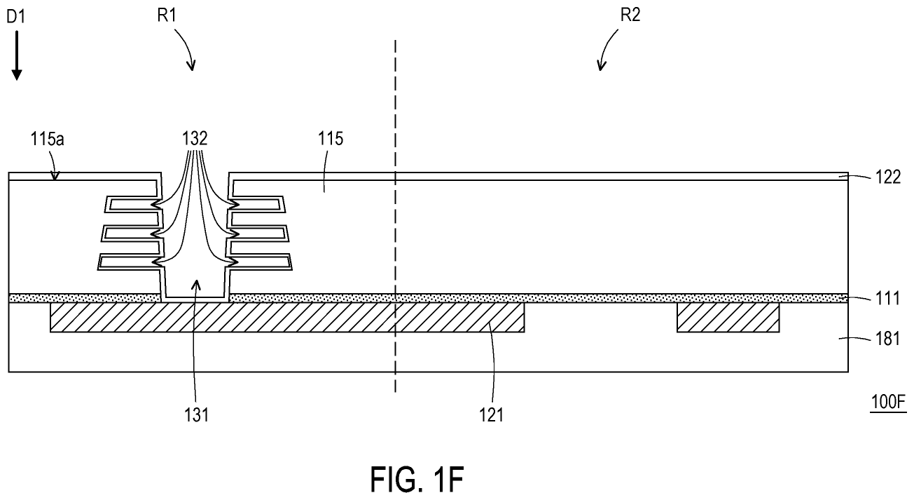

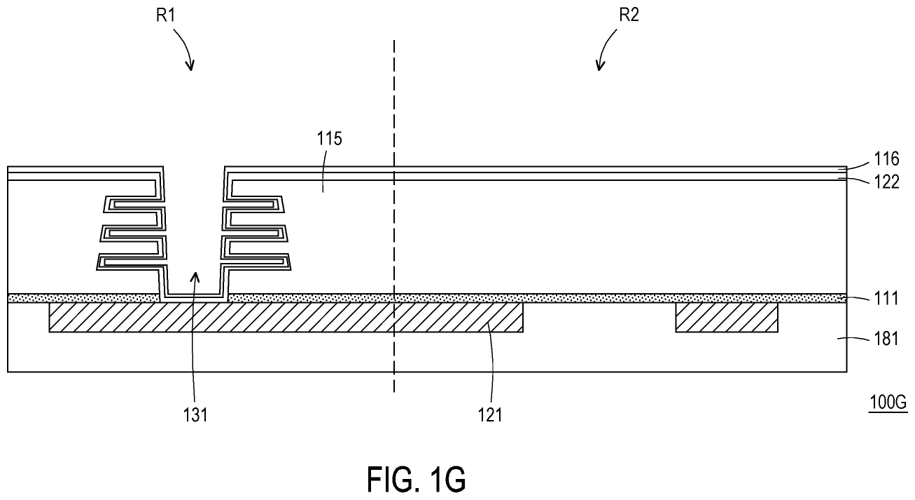

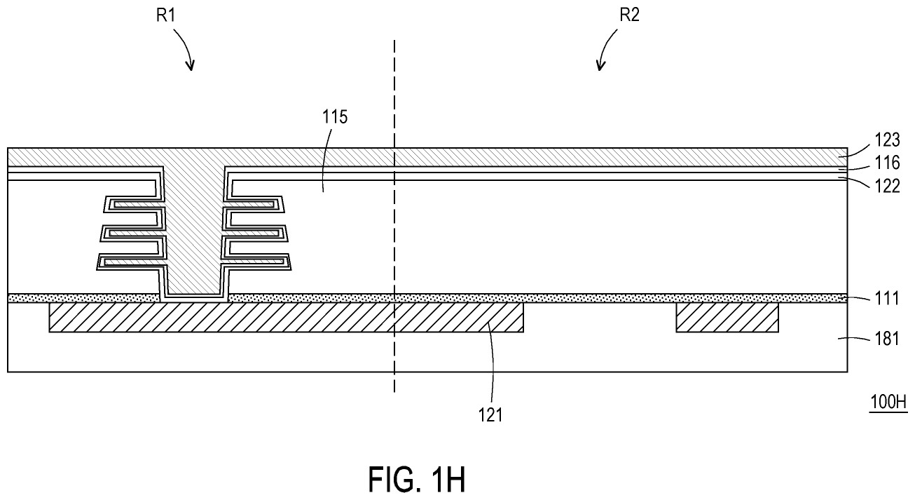

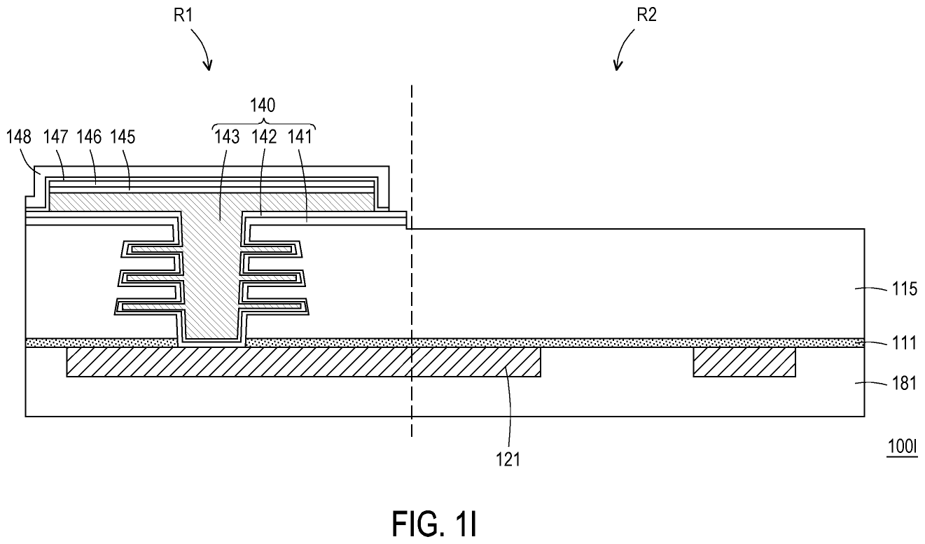

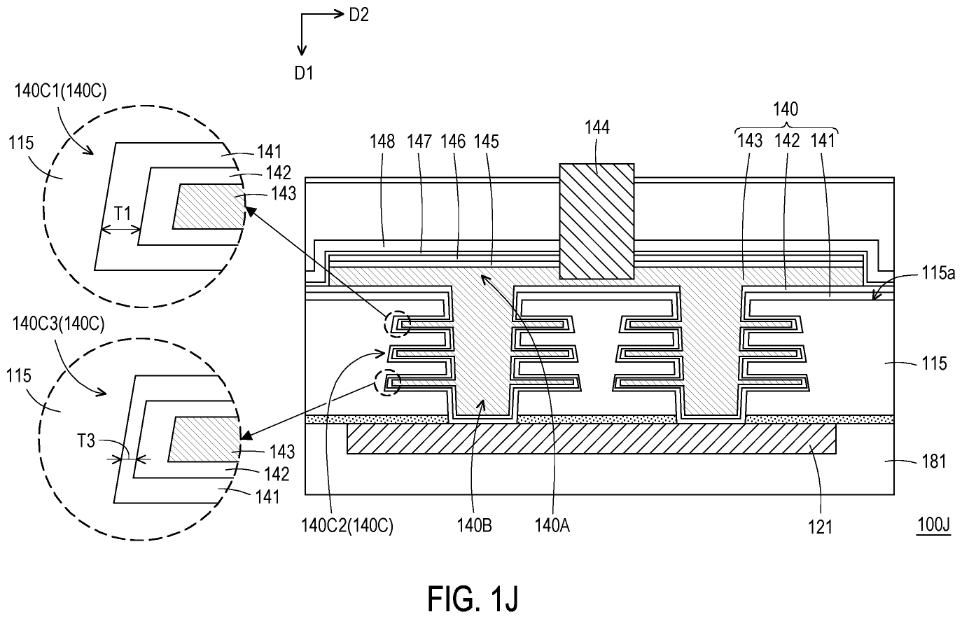

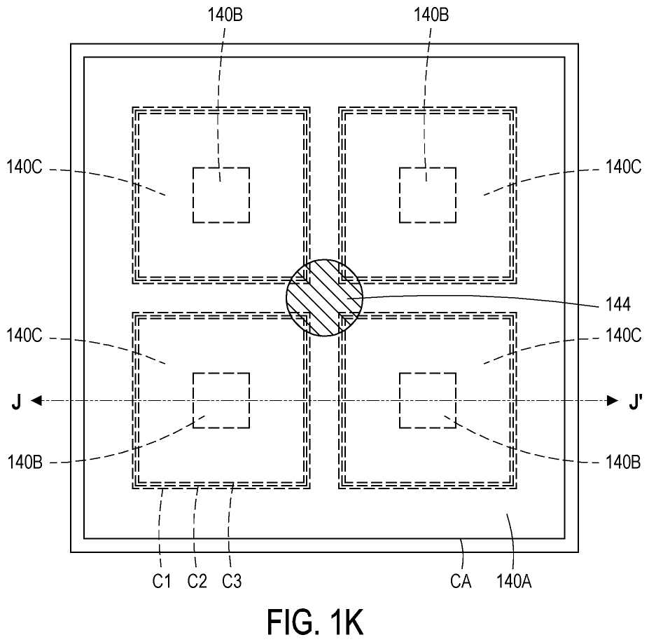

FIGS. 1A-1J illustrate various cross-sectional views of some embodiments of a method of forming an electronic component.

As shown in cross-sectional view of FIG. 1A, a structure 100A including a substrate 181 and a plurality of layers (e.g., layers 121, 111, 112, 113) or regions disposed on the substrate 181 or embedded in the substrate 181 is provided. The plurality of layers or regions may be formed by a suitable process such as low pressure chemical vapor deposition (LPCVD), plasma enhanced chemical vapor deposition (PECVD), high density chemical plasma vapor deposition (HDPCVD), atomic layer deposition (ALD), physical vapor deposition (PVD) or high density plasma chemical vapor deposition (HDPCVD), vapor transport deposition (VTD), ion implantation process, diffusion process, oxidation process, or the like. The plurality of layers or regions disposed on the substrate 181 or embedded in the substrate 181 may be considered a portion of the substrate 181. Additionally, the substrate 181 as shown in the drawings may be illustrated as an example.

The substrate 181 may include a semiconductor substrate (e.g., a silicon (Si) substrate or a semiconductor wafer), a printed circuit board (e.g., an FR-4 printed circuit board), a glass substrate, a ceramic substrate, or a polymer substrate, but the disclosure is not limited thereto. A structure including a semiconductor substrate may be referred as a semiconductor structure. Take a semiconductor wafer as an example, the substrate 181 includes a crystalline silicon wafer. The substrate 181 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. A plurality of layers or regions disposed on the substrate 181 (e.g., a semiconductor substrate) or embedded in the substrate may be considered a portion of the substrate. In some alternative embodiments, the substrate 181 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. The substrate 181 may further include interconnect structure formed over and electrically connected to the various doped regions. The interconnect structure may include a circuitry fabricated by front end of line (FEOL) or middle end of line (MEOL) processes. For example, an electrically conductive via may penetrate a dielectric region and electrically connect to a gate electrode, a source region, or a drain region.

Layers disposed on the substrate 181 include a first insulating layer 111, a plurality of second insulating layer 112, and a plurality of third insulating layer 113. The second insulating layers 112 and the third insulating layers 113 are alternately stacked to form a corresponding stacked structure 171A, and each third insulating layer 113 is sandwiched between two adjacent second insulating layers 112. A material of the first insulating layer 111, a material of the second insulating layer 112, and a material of the third insulating layer 113 are different from each other. The first insulating layer 111 may be referred as an etching stop layer, and/or a material of the first insulating layer 111 may include silicon carbide (e.g., SiC). The second insulating layer 112 may be referred as a plasma enhanced oxide (PEOX) layer, and/or a material of the second insulating layer 112 may include silicon carbon oxide (SiCO/SiOC). The third insulating layer 113 may be referred as a sacrificial layer, and/or a material of the third insulating layer 113 may include silicon oxide (SiO) or silicon nitride (SiN).

As shown in the cross-sectional view of FIG. 1B, a structure 100B including a stacked structure 171B is formed. The stacked structure 171B as shown in FIG. 1B may be formed by performing an etching process on the structure (e.g., the stacked structure 171A or a structure including thereof) as shown in FIG. 1A. Additionally, for simply or clearly, a certain layer (e.g., the second insulating layer 112 or the third insulating layer 113, but not limited) may have a same reference sign in the different drawings before and after being patterned.

The stacked structure 171B includes alternately stacked second insulating layers 112 and third insulating layers 113. A three-dimensional shape of the stacked structure 171B may be a cone or a pyramid. In a cross-section view (e.g., the drawing as shown in FIG. 1B), an outline of the stacked structure 171B is a trapezoid substantially. Moreover, in a top view, a corresponding surface area of each layer of the plurality of third insulating layers 113 may gradually increase toward the direction approaching the substrate 181.

As shown in the cross-sectional view of FIG. 1C, a structure 100C including a fourth insulating layer 114 is formed. A material of the fourth insulating layer 114 is different from the material of the third insulating layer 113. The fourth insulating layer 114 may be formed by an appropriate deposition process, then a planarization process (e.g., a chemical mechanical polishing (CMP) process) may be performed for forming a corresponding flat top surface.

The material of the fourth insulating layer 114 may be the same or similar to the material of the second insulating layer 112. Therefore, there may be no clear interface between the second insulating layer 112 and the fourth insulating layer 114. Structurally, the second insulating layer 112 and the fourth insulating layer 114 with a same or similar material may be regarded as a same insulating layer and may be referred as a fifth insulating layer 115. That is, the plurality of third insulating layers 113 may be regarded as parallelly and respectively embedded in the fifth insulating layer 115. A planarization process (e.g., a chemical mechanical polishing (CMP) process) may be performed to the fifth insulating layer 115 (e.g., the topmost second insulating layer 112 or a portion of fourth insulating layer 114 disposed thereon) for forming a corresponding flat top surface 115a.

As shown in the cross-sectional view of FIG. 1D, a structure 100D including at least one vertical trench 131 is formed. The vertical trench 131 may be formed by an appropriate etching process. The vertical trench 131 vertically penetrates through the fifth insulating layer 115 and the third insulating layers 113 embedded therein. A portion of the first conductive layer 121 disposed between the fifth insulating layer 115 and the substrate 181 is exposed by the vertical trench 131. Moreover, a portion of each third insulating layers 113 is laterally exposed by the vertical trench 131. The pattern of the vertical trench 131 is not limited in the disclosure. For example, in a top view, the pattern of the vertical trench 131 may be quadrilateral (e.g., a rectangle or a square) or circular.

As shown in the cross-sectional view of FIG. 1E, a structure 100E including a plurality of horizontal trenches 132 horizontally extending from the vertical trench 131 into the fifth insulating layer 115 is formed. The third insulating layers 113 (as shown in FIG. 1D) laterally exposed by the vertical trench 131 are removed by a wet etching process to form the horizontal trenches 132 (as shown in FIG. 1E). Thereby, the contour of the horizontal trenches 132 substantially corresponds to the shape of the third insulating layers 113.

As shown in the cross-sectional view of FIG. 1F, a structure 100F including a second conductive layer 122 is formed. The second conductive layer 122 is formed by an appropriate deposition process, for example, including an ALD process. The second conductive layer 122 is disposed on the top surface 115a of the fifth insulating layer 115 and extended into the vertical trench 131, and is further extended into the horizontal trenches 132 extending from the vertical trench 131 and disposed on the portion of the first conductive layer 121 exposed by the vertical trench 131. The second conductive layer 122 may be conformally cover a portion of the outside surface of the fifth insulating layer 115 and the portion of the first conductive layer 121 exposed by the vertical trench 131. That is, the second conductive layer 122 may not fill the entire vertical trench 131 and the entire horizontal trenches 132 essentially.

The second conductive layer 122 may be a stacked film structure of a plurality of conductive layers of different materials. For example, the second conductive layer 122 may be a stacked film structure of a metal nitride (e.g., tantalum nitride (TaN), titanium nitride (TiN), tungsten nitride (e.g., W₂N, WN, or WN₂), ruthenium nitride (RuN), or a stack or composition thereabove) layer, a metal (e.g, tantalum (Ta), titanium (Ti), ruthenium (Ru), tungsten (W), iridium (Ir), platinum (Pt), or a stack or composition thereabove) layer and/or a metal nitride layer. A metal nitride layer may be referred as a conductive glue layer or a barrier layer.

Depositing the second conductive layer 122 may include a conformal deposition process, for example, a CVD process, an ALD process, or the like, and/or a combination thereof. The conformal deposition process may include performing N deposition cycles until a desired thickness for the second conductive layer 122 is achieved, where N is any positive integer. In an embodiment, an optional inhibitor (e.g., a self-assembled monolayer (SAM) or small molecule inhibitor (SMI)) may be formed to cover the outer surfaces of the fifth insulating layer 115 and first conductive layer 121 exposed by the vertical trench 131 prior to conformal deposition process to further promote a substantially top-down directionality of a conformal deposition process. After the conformal deposition process is completed, an optional annealing process, for example at a temperature in a range of 200° C. to 600° C. in an inert gas (e.g., Ar, He, N₂, or the like) environment, may be performed. Then, a precursor may be provided over the fifth insulating layer 115, and the precursor flows into the vertical trench 131 and further into the horizontal trenches 132. The precursor may be selected from metal organic compounds, metal halides, metal carbonyls, metal complex, or the like with a relatively sticking coefficient. For example, the precursor may be a metal halide. In an embodiment where the target metal layer is a TiN layer, the precursor may be TiCl₄. Due to the relatively corresponding sticking coefficient of the precursor, the first precursor may first accumulate and attach to the top surface 115a of the fifth insulating layer 115, then an upper sidewall of the vertical trench 131 and an upper horizontal trench 132, and further then a lower sidewall of the vertical trench 131 and a lower horizontal trench 132. That is, a surface concentration or density of the precursor may decrease along diffusion path thereof. For example, a surface concentration or density of the precursor may substantially decrease along a direction D1 form the top of the vertical trench 131 towards the bottom of the vertical trench 131. As such, a deposition thickness of the second conductive layer 122 may decrease along the direction D1. For example, a deposition thickness of the second conductive layer 122 on the sidewall of the upper horizontal trench 132 is thicker than a deposition thickness of the second conductive layer 122 on the sidewall of the lower horizontal trench 132.

As shown in the cross-sectional view of FIG. 1G, a structure 100G including a dielectric layer 116 is formed. The dielectric layer 116 is formed by an appropriate deposition process, for example, an ALD process. The dielectric layer 116 is disposed on the outside surface of the second conductive layer 122. The dielectric layer 116 may be conformally cover a portion of the outside surface of the second conductive layer 122. That is, the dielectric layer 116 may not fill the entire vertical trench 131 and the entire horizontal trenches 132 (as labeled in FIGS. 1E and 1F, and for simply or clearly, skipping labeled in FIG. 1G) essentially.

The dielectric layer 116 may be a stacked film structure of a plurality of dielectric layers of different materials. For example, the dielectric layer 116 may be a stacked film structure of high-K dielectric material layers. The high-K dielectric material may, for example, include silicon nitride (SiN; e.g., Si₃N₄), aluminum oxide (AlO; e.g., Al₂O₃), hafnium silicates (HfSiON), tantalum oxide (TaO; e.g., Ta₂O₅), zirconium oxide (ZrO; e.g., ZrO₂), hafnium oxide (HfO; e.g., HfO₂), titanium oxide (TiO; e.g., TiO₂), barium strontium titanate oxide (BSTA; e.g., Ba_{0.8}Sr_{0.2}TiO₃), strontium titanate oxide (STO; e.g., SrTiO₃), or combinations thereof. In an embodiment, the dielectric layer 116 includes a laminate such as a zirconium oxide-aluminum oxide-zirconium oxide (e.g., ZrO₂—Al₂O₃—ZrO₂) laminate, sometimes referred to as a ZAZ laminate.

As shown in the cross-sectional view of FIG. 1H, a structure 100H including a third conductive layer 123 is formed. The third conductive layer 123 is formed by an appropriate process, for example, a deposition process (e.g., an ALD process) and/or a planting process (e.g., an electroplating process). The third conductive layer 123 and second conductive layer 122 are physically and electrically separated by the dielectric layer 116.

The third conductive layer 123 is disposed on the top surface of the fifth insulating layer 115 and extended into the vertical trench 131 (as shown in FIG. 1G), and is further extended into the horizontal trenches 132 extending from the vertical trench 131 (as shown in FIG. 1G). Except for the space occupied by the second conductive layer 122 and the dielectric layer 116, the third conductive layer 123 may substantially fill other remaining spaces of the vertical trench 131 and the horizontal trenches 132, but the disclosure is not limited thereto.

The material of a portion of the third conductive layer 123 may be the same or similar to the material of the second conductive layer 122. For example, the material of the seed layer of the third conductive layer 123 may be the same or similar to the material of the second conductive layer 122.

Additionally, a planarization process (e.g., a chemical mechanical polishing (CMP) process) may be further performed on the third conductive layer 123 for forming a corresponding flat top surface, but the disclosure is not limited thereto.

As shown in the cross-sectional view of FIG. 1I, a structure 100I including a capacitor 140 is formed. For example, the structure 100H as shown in FIG. 1H is performed to an appropriate patterning process to form the structure 100I including a capacitor 140 as shown in FIG. 1I. The aforementioned patterning process may include a lithography and etching process to remove a portion of the second conductive layer 122, a portion of the dielectric layer 116, and a portion of the third conductive layer 123, to respectively form a first electrode 141, an insulator 142, and a second electrode 143 of the capacitor 140. That is, the first electrode 141 corresponds to a portion of the second conductive layer 122, the insulator 142 corresponds to a portion of the dielectric layer 116, and the second electrode 143 corresponds to a portion of the third conductive layer 123. The capacitor 140 may be referred as a metal-insulator-metal (MIM) capacitor.

One or more insulating or dielectric layers (e.g., layers 145, 146, 147, 148) may be formed on the capacitor 140 for performing a subsequent processing. The aforementioned insulating or dielectric layers 145, 146, 147, 148 may include a ZAZ laminate, a SiO layer, a SiN layer, a SiC layer, a SiOC layer, a SiON layer, a SiCN layer, a SiOCN layer, a undoped silicate glass (USG) layer, and/or a combination or stack thereof, but the disclosure is not limited thereto. At least one of the layers 145, 146, 147, 148 may be referred as a high-K dielectric layer, at least one of the layers 145, 146, 147, 148 may be referred as a barrier layer, at least one of the layers 145, 146, 147, 148 may be referred as an etching stop layer, and/or at least one of the layers 145, 146, 147, 148 may be referred as a capping layer, but the disclosure is not limited thereto.

FIG. 1J illustrates a cross-sectional view of some embodiments of an electronic component. FIG. 1K illustrates a top view of some embodiments of an electronic component. FIG. 1J may be a cross-sectional view corresponding to the J-J′ crossline as shown in FIG. 1I. It is worth noting that the conductor is essentially not on the cross-sectional view corresponding to the J-J′ crossline as shown in FIG. 1I, but in order to understand the relative relationship of the structure, the relative position of the conductor is still shown in FIG. 1K.

Referring to FIGS. 1J and 1K, the electronic component 100J includes a least one capacitor 140. The capacitor 140 has a main portion 140A, at least one branch portion 140B, and a plurality of twig portions 140C. The branch portion 140B extends from the main portion 140A in a first direction D1. The twig portions 140C extend from corresponding branch portion 140B in a second direction D2. The main portion 140A, the branch portion 140B, and the twig portions 140C all include corresponding first electrodes 141, second electrodes 143, and insulators 142 disposed between the corresponding first electrode 141 and the corresponding second electrode 143. The first direction D1 is not parallel to the second direction D2. For example, the first direction D1 is substantially perpendicular to the second direction D2.

In an embodiment, the electronic component 100J further includes an insulating layer 115. The main portion 140A is disposed on the insulating layer 115. The branch portion 140B vertically penetrates through the insulating layer 115. The twig portions 140C horizontally or laterally extend from the corresponding branch portion 140B and are respectively embedded in the insulating layer 115.

In an embodiment, the insulating layer 115 is a homogeneous material. The aforementioned homogeneous material means one material of uniform composition throughout or a material, consisting of a combination of materials, that cannot be disjointed or separated into different materials by mechanical actions such as breaking, shearing, cutting, sawing, and grinding. In an embodiment, the insulating layer 115 with a homogeneous material has no interface within formed due to different materials.

In an embodiment, the peripheral contours of the plurality of twig portions 140C gradually increase away from the main portion 140A. For example, a first twig portion 140C1, a second twig portion 140C2, and a third twig portion 140C3 extend horizontally from a same branch portion 140B. A vertically distance between the main portion 140A and the first twig portion 140C1 is smaller than a vertically distance between the main portion 140A and the second twig portion 140C2, and a vertically distance between the main portion 140A and the second twig portion 140C2 is smaller than a vertically distance between the main portion 140A and the third twig portion 140C3. In a top view (e.g., as shown in FIG. 1K), a peripheral contour C3 of the third twig portion 140C3 is larger than a peripheral contour C2 of the second twig portion 140C2, and the peripheral contour C2 of the second twig portion 140C2 is larger than a peripheral contour C1 of the first twig portion 140C1.

In an embodiment, in the top view (e.g., as shown in FIG. 1K), the plurality of twig portions 140C extending horizontally from a same branch portion 140B are overlapped. For example, the first twig portion 140C1, the second twig portion 140C2, and the third twig portion 140C3 are overlapped.

In an embodiment, in the top view (e.g., as shown in FIG. 1K), a peripheral contour CA of the main portion 140A is larger than the peripheral contour of each of the twig portions 140C.

In an embodiment, the first electrode 141 is formed by an atomic layer deposition (ALD) process. In an embodiment, the thickness of the first electrodes 141 of the plurality of twig portions 140C gradually decrease away from the main portion 140A. For example, the thickness T1 of the first electrode 141 of the first twig portion 140C1 is larger than the thickness (for simply and clearly, not directly labeled in the drawing) of the first electrode 141 of the second twig portion 140C2, and the thickness of the first electrode 141 of the second twig portion 140C2 is larger than the thickness T3 of the first electrode 141 of the third twig portion 140C.

In an embodiment, the electronic component 100J further includes a substrate 181. The capacitor 140 is disposed on the substrate 181. A conductive layer 121 is disposed on the substrate 181. A portion of the conductive layer 121 disposed between the capacitor 140 and the substrate 181 is electrically connected to the first electrode 141 of the capacitor 140.

In an embodiment, the electronic component 100J further includes a conductor 144. The conductor 144 is disposed on the conductor 144 and penetrates through the insulating or dielectric layers 145, 146, 147, 148 disposed on the capacitor 140 to be electrically connected to the second electrode 143 of the capacitor 140. In an embodiment, the conductor 144 is embedded in the second electrode 143 of the main portion 140A.

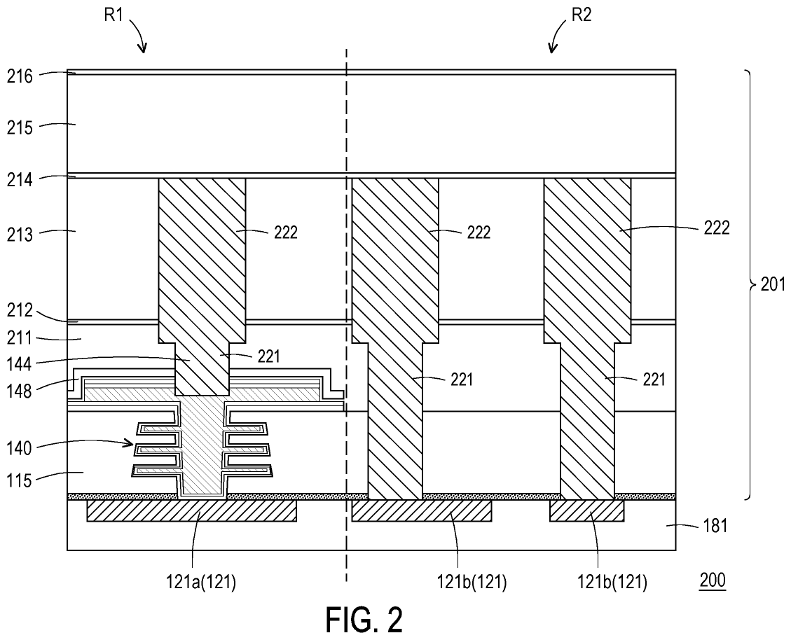

FIG. 2 illustrates a various cross-sectional view of some embodiments of an electronic component.

The electronic component 200 as shown in FIG. 2 may be a portion of a die, but the disclosure is not limited thereto. For example, the substrate 181 includes a first region R1 and a second region R2. Considering to a corresponding structure, the first region R1 may be referred as a capacitance area, and the second region R2 may be referred as a device area.

In an embodiment, the capacitor 140 is within a back-end-of-line (BEOL) structure of the die. That is, the capacitor 140 is referred as a portion of the interconnect structure (e.g., a BEOL interconnect structure) 201.

The interconnect structure may include one or more corresponding insulating or dielectric layers (e.g., layers 211, 212, 213, 214, 215, 216) and one or more corresponding conductive layers (e.g., layers 221, 222). A layout design of the conductive layers may be adjusted according to actual needs, and is not limited by the disclosure. A portion of the conductive layers may be a corresponding conductive line and referred as a Mx layer, where x is zero or any positive integer. A portion of the conductive layers may be a corresponding conductive via and referred as a Vy layer, where y is zero or any positive integer. In an embodiment, the conductor 144 is a conductive via and/or a portion of the interconnect structure 201.

A portion 121a of the conductive layer 121 corresponding to the first region R1 is electrically connected to the first electrode 141 of the capacitor 140. A portion 121b of the conductive layer 121 corresponding to the second region R2 and/or away from the capacitor 140 may be a portion of an interconnector to be electrically connected a source, a drain, or a gate of a transistor.

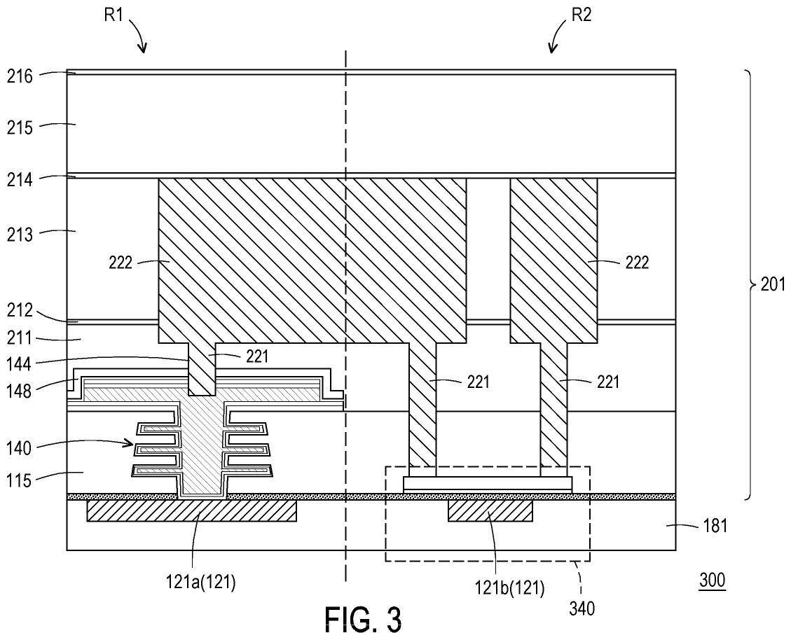

FIG. 3 illustrates a various cross-sectional view of some embodiments of an electronic component.

The electronic component 300 as shown in FIG. 3 may be a portion of a die or a panel (e.g., a display panel), but the disclosure is not limited thereto. In an embodiment where the electronic component 300 is a die, the substrate 181 is a semiconductor substrate. In an embodiment where the electronic component 300 is a portion of a panel (e.g., a display panel), the substrate 181 is a printed circuit board or a glass substrate.

The electronic component 300 may further include a thin film transistor (TFT). The thin film transistor 340 may be a bottom gate thin film transistor, a top gate thin film transistor, or a dual gate thin film transistor. For example, thin film transistor 340 as shown in FIG. 3 may be referred as a bottom gate thin film transistor. A structure with one thin film transistor (e.g., the thin film transistor 340) being electrically connected to one capacitor (e.g., the capacitor 140) may be referred as a 1T1C structure. In an embodiment, a structure with one or more thin film transistors being electrically connected to one or more capacitors includes, for example, a 2T1C structure, a 3T1C/2C structure, a 4T1C/2C structure, or the like.

In an embodiment, a portion of the conductor 144 and a portion of the source/drain of the thin film transistor 340 are of the same film layer, but the disclosure is not limited thereto.

In an embodiment, a portion 121b of the conductive layer 121 away from the capacitor 140 is a portion of the gate of the thin film transistor 340, but the disclosure is not limited thereto.

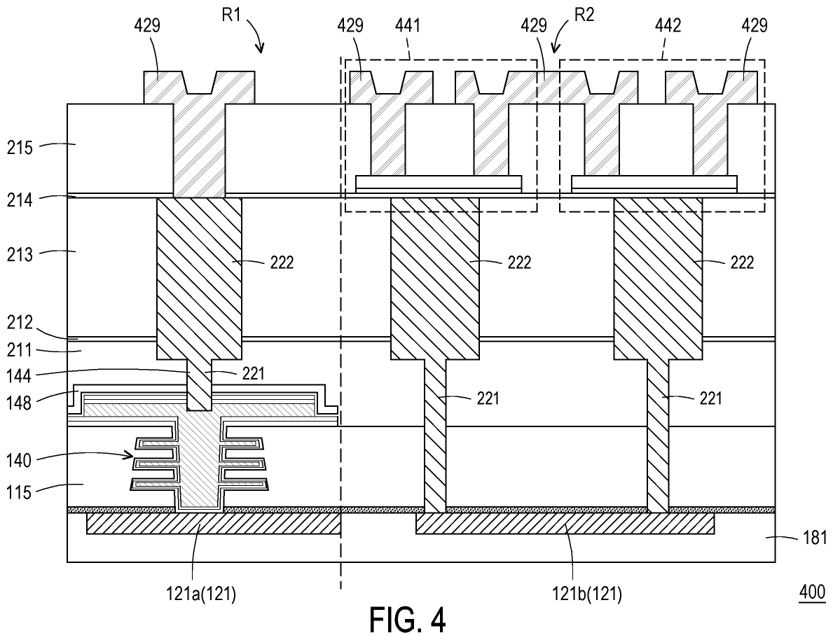

FIG. 4 illustrates a various cross-sectional view of some embodiments of an electronic component.

The electronic component 400 as shown in FIG. 4 may be a portion of a die or a panel, but the disclosure is not limited thereto. The electronic component 400 may further include at least one thin film transistor (e.g., the thin film transistor 441 and/or the thin film transistor 442). In an embodiment, a portion of the conductor 144 and a portion of the gate of the thin film transistor (e.g., the thin film transistor 441 and/or the thin film transistor 442) are a portion of the same film layer, but the disclosure is not limited thereto. An electrode of the capacitor 140, the thin film transistor 441 and/or the thin film transistor 442 is electrically connected to a corresponding contact terminal 429.

In an embodiment, the thin film transistor 441 includes an n-type channel and be referred as a n-type transistor. The thin film transistor 442 includes an p-type channel and be referred as a p-type transistor. The gates of the thin film transistor 441 and the thin film transistor 442 are electrically connected to each other, the drain of the thin film transistor 441 and the source the thin film transistor 442 are electrically connected to each other.

In an embodiment, the thin film transistor 441 and the thin film transistor 442 are integrated as an inverter (e.g., a NOT gate), but the disclosure is not limited thereto. For example, the gates of an n-type transistor and a p-type transistor are electrically connected to an input, the source of the n-type transistor is electrically connected to a Vss source via a contact terminal, the drain of the n-type transistor and the source of the p-type transistor are electrically connected to an output via a contact terminal, and the drain of the p-type transistor is electrically connected to a Vdd source via a contact terminal.

The thin film transistor 441, the thin film transistor 442, and other one or more transistors not shown in FIG. 4 may be integrated as an AND gate, a NAND gate, an OR gate, a NOR gate, an XOR gate, or an XNOR gate.

It is worth noting that conductors not connected in the drawings may be electrically connected through other conductors not shown or in cross-sections not shown. For example, the portion 121b of the conductive layer 121 away from the capacitor 140 and being electrically connected to thin film transistors 441, 442 is electrically connected to the portion 121a of the conductive layer 121 overlapped the capacitor 140.

In an embodiment, the contact terminals 429 includes a die pad and/or a controlled collapse of chip connection (C4) bump, but the disclosure is not limited thereto.

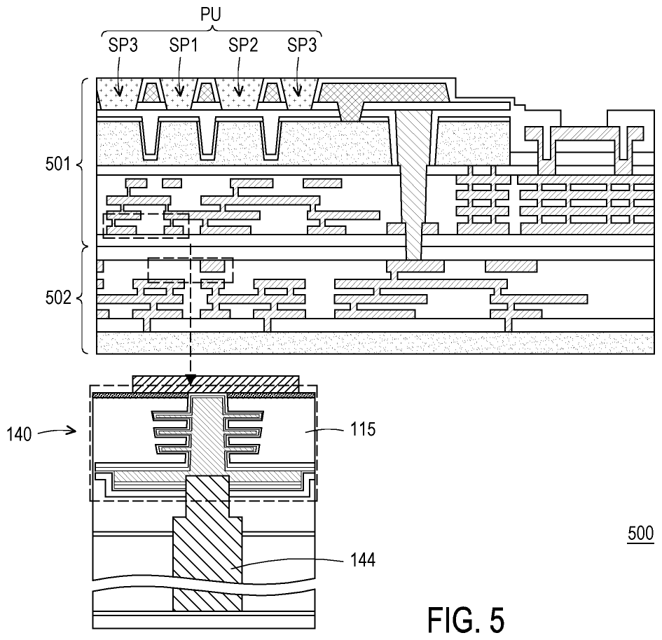

FIG. 5 illustrates a various cross-sectional view of some embodiments of an electronic component.

The electronic component 500 as shown in FIG. 5 may be a portion of a stacked die or a package including a plurality of dies, but the disclosure is not limited thereto. For example, the electronic component 500 includes dies 501, 502 which are stacked. The BEOL structure of the first die 501 and the BEOL structure of the second die 502 may be bonded face to face. At least one of the BEOL structures include a corresponding capacitor 140.

The electronic component 500 may be heterogeneous integration with a plurality of dies. For example, the die 501 is a system-on-Chip (SoC) die, and the die 502 is an application specific integrated circuit (ASIC) die. In an embodiment, the die 501 further includes a CMOS image sensor (CIS) pixel structure. A device within the CIS pixel structure is electrically connected to a corresponding circuit within the BEOL structure by an appropriate conductor (e.g., a through silicon via (TSV)). A pixel (may be referred as a pixel unit PU) include at least one first sub-pixel (e.g., a red pixel) SP1, at least one second sub-pixel (e.g., a green pixel) SP2, and/or at least one third sub-pixel (e.g., a blue pixel) SP3. A plurality of pixel units PU may be arranged in an array. One or more pixels PU may correspond or be electrically connected to one or more corresponding capacitors 140.

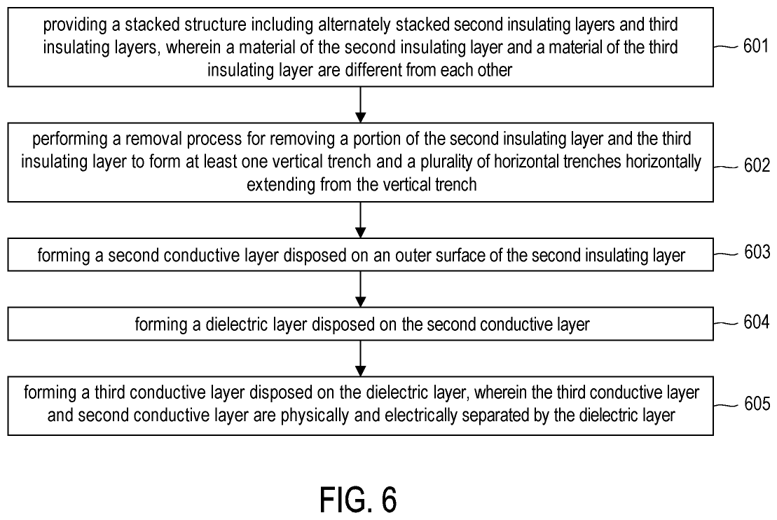

FIG. 6 illustrates a flow diagram of some embodiments of a method of forming an electronic component.

At act 601, a stacked structure including alternately stacked second insulating layers and third insulating layers is provided. A material of the second insulating layer and a material of the third insulating layer are different from each other. FIGS. 1A, 1B, and/or 1C illustrate cross-sectional views corresponding to various embodiments of act 601. The stacked structure may be further disposed on a first conductive layer.

In an embodiment, the stacked structure is disposed on a substrate. An area of the topmost surface (e.g., the surface furthest away from the substrate) of the stacked structure is greater than an area of the bottommost surface (e.g., the surface closest to the substrate) of the stacked structure, and in a top view, the area of the topmost surface is overlapped and within the area of the bottommost surface. That is, in a cross-section view (e.g., the drawing as shown in FIG. 1B), an outline of the stacked structure may be a trapezoid. FIG. 1B illustrates a cross-sectional view corresponding to various embodiments of act 601.

In an embodiment, the stacked structure is embedded in a fourth insulating layer. The second insulating layer and the fourth insulating layer with a same or similar material may be regarded as a same insulating layer and may be referred as a fifth insulating layer. FIG. 1C illustrates a cross-sectional view corresponding to various embodiments of act 601.

At act 602, a removal process is performed for removing a portion of the fifth insulating layer (or, a portion of the second insulating layer) and the third insulating layer to form at least one first trench (e.g., the vertical trench 131) and a plurality of second trenches (e.g., the horizontal trenches 132) laterally or horizontally extending from the first trench. FIG. 1E illustrates a cross-sectional view corresponding to various embodiments of act 602. The first trench may be further exposed a portion of the first conductive layer.

In an embodiment, a first removal process is performed for removing a portion of the fifth insulating layer (or, a portion of the second insulating layer), and a portion of the third insulating layer to form at least one first trench. Then, a second removal process is performed for removing the remained third insulating layer to form a plurality of second trenches horizontally extending from the first trench. FIGS. 1D-1E illustrate cross-sectional views corresponding to various embodiments of act 602.

At act 603, after performing the removal process, an appropriate deposition process is performed for forming a second conductive layer disposed on an outer surface of the fifth insulating (or, a portion of the second insulating layer). FIG. 1F illustrates a cross-sectional view corresponding to various embodiments of act 603. The second conductive layer may be further disposed on the portion of the first conductive layer exposed by the first trench.

In an embodiment, the second conductive layer is formed including an ALD process.

In an embodiment, the second conductive layer is conformally cover a portion of the outside surface of the fifth insulating layer and the portion of the first conductive layer exposed by the first trench. In an embodiment, the second conductive layer is not fill the entire first trench and the entire second trenches essentially.

At act 604, after forming the second conductive layer, a dielectric layer disposed on the second conductive layer is formed. FIG. 1G illustrates a cross-sectional view corresponding to various embodiments of act 604.

In an embodiment, the dielectric layer is conformally cover a portion of the outside surface of the second conductive layer. In an embodiment, the dielectric layer may not fill the entire first trench and the entire second trenches essentially.

At act 605, after forming the dielectric layer, a third conductive layer disposed on the dielectric layer is formed. The third conductive layer and second conductive layer are physically and electrically separated by the dielectric layer. FIG. 1H or 1I illustrate cross-sectional views corresponding to various embodiments of act 605.

Accordingly, in some embodiments, the present disclosure relates to an electronic component including at least one capacitor. The electronic component may have a better heat dissipation. The capacitor includes a main portion, at least one branch portion, and a plurality of twig portion. The branch portion extends from the main portion in a first direction. The twig portions extend from corresponding branch portion in a first direction. The main portion, the branch portion, and the twig portions all include corresponding first electrodes, second electrodes, and insulators disposed between the first electrode and the second electrode. As such, the capacitor of the disclosure may have better or more capacitance. For example, in a top view, under the same unit area, the capacitor of the disclosure may have a higher capacitance value.

In accordance with some embodiments of the present disclosure, a structure comprises an insulating layer and a metal-insulator-metal (MIM) capacitor. The insulating layer is disposed on a substrate. The MIM capacitor is disposed on the substrate. The MIM capacitor comprises a main portion, at least one branch portion, and a plurality of twig portions. The main portion is disposed on the insulating layer. The branch portion extends from the main portion. The twig portions extend from the branch portion and are respectively embedded in the insulating layer. In an embodiment, in a top view, peripheral contours of the twig portions gradually increase away from the main portion. In an embodiment, in a top view, a peripheral contour of the main portion is larger than peripheral contours of the twig portions. In an embodiment, adjacent two of the twig portions are electrically connected only through the branch portion. In an embodiment, a portion of the insulating layer is disposed between adjacent two of the twig portions. In an embodiment, the insulating layer is a homogeneous material. In an embodiment, the branch portion penetrates through the insulating layer, and the twig portions laterally extend from the branch portion. In an embodiment, the structure further comprises a conductor embedded in the main portion of the MIM capacitor. In an embodiment, the structure further comprises at least one thin film transistor (TFT) electrically connected to the MIM capacitor. In an embodiment, the structure further comprises at least one image sensor pixel electrically connected to the MIM capacitor.

In accordance with some embodiments of the present disclosure, a structure comprises a metal-insulator-metal (MIM) capacitor. The MIM capacitor comprises a second electrode, a dielectric layer, a first electrode. The second electrode has a main portion, at least one branch portion extending from the main portion, and a plurality of twig portions, extending from the branch portion. The dielectric layer covers a lower surface of the main portion, and extends for completely covering outer surfaces of the branch portion and twig portions of the second electrode. The first electrode conformally covers the dielectric layer, wherein the first electrode and second electrode are physically and electrically separated by the dielectric layer. In an embodiment, the first electrode is a structurally continuous film layer. In an embodiment, the twig portions of the second electrode are structurally respectively annularly extended from the branch portion. In an embodiment, the twig portions are different in sizes. In an embodiment, the structure further comprises a conductor embedded in the main portion of the second electrode.

In accordance with some embodiments of the present disclosure, a method comprises: providing a stacked structure including alternately stacked second insulating layers and third insulating layers, wherein a material of the second insulating layer and a material of the third insulating layer are different from each other; performing a removal process for removing a portion of the second insulating layer and the third insulating layer to form at least one first trench and a plurality of second trenches laterally extending from the first trench; forming a second conductive layer disposed on an outer surface of the second insulating layer; forming a dielectric layer disposed on the second conductive layer; and forming a third conductive layer disposed on the dielectric layer, wherein the third conductive layer and second conductive layer are physically and electrically separated by the dielectric layer. In an embodiment, in a top view, an area of a topmost surface of the stacked structure is overlapped and within an area of a bottommost surface of the stacked structure; the stacked structure is disposed on a substrate, the topmost surface is the surface of the stacked structure furthest away from the substrate, and the bottommost surface is the surface of the stacked structure closest to the substrate. In an embodiment, the method further comprises: forming a fourth insulating layer laterally covering the stacked structure, wherein a material of the fourth insulating layer is essentially the same as the material of the second insulating layer. In an embodiment, the method further comprises: forming a first conductive layer disposed on a substrate; and forming a first insulating layer disposed on the first conductive layer; wherein the material of the second insulating layer, the material of the third insulating layer, and a material of the first insulating layer are different from each other; a portion of the first insulating layer is removed by the removal process; and the second conductive layer is further disposed on a portion of the first conductive layer exposed by the first trench. In an embodiment, the removal process comprises a first removal process and a second removal process, wherein the portion of the first insulating layer, the portion of the second insulating layer, and a portion of the third insulating layer are removed by the first removal process for forming the first trench; and a remained portion of the third insulating layer are removed by the second removal process for forming the second trenches.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
an insulating layer disposed on a substrate; and
a metal-insulator-metal (MIM) capacitor disposed on the substrate, wherein the MIM capacitor comprises:
a main portion, disposed on the insulating layer;
at least one branch portion, extending from the main portion; and
a plurality of twig portions, extending from the branch portion and being respectively embedded in the insulating layer.

2. The structure of claim 1, wherein in a top view, peripheral contours of the twig portions gradually increase away from the main portion.

3. The structure of claim 1, wherein in a top view, a peripheral contour of the main portion is larger than peripheral contours of the twig portions.

4. The structure of claim 1, wherein adjacent two of the twig portions are electrically connected only through the branch portion.

5. The structure of claim 1, wherein a portion of the insulating layer is disposed between adjacent two of the twig portions.

6. The structure of claim 1, wherein the insulating layer is a homogeneous material.

7. The structure of claim 1, wherein:
the branch portion penetrates through the insulating layer; and
the twig portions laterally extend from the branch portion.

8. The structure of claim 1, further comprising:
a conductor, embedded in the main portion of the MIM capacitor.

9. The structure of claim 1, further comprising:
at least one thin film transistor (TFT), electrically connected to the MIM capacitor.

10. The structure of claim 1, further comprising:
at least one image sensor pixel electrically connected to the MIM capacitor.

11. A structure, comprising:
a metal-insulator-metal (MIM) capacitor, comprising:
a second electrode, having a main portion, at least one branch portion extending from the main portion, and a plurality of twig portions extending from the branch portion;
a dielectric layer, covering a lower surface of the main portion, and extending for completely covering outer surfaces of the branch portion and twig portions of the second electrode; and
a first electrode, conformally covering the dielectric layer, wherein the first electrode and second electrode are physically and electrically separated by the dielectric layer.

12. The structure of claim 11, wherein the first electrode is a structurally continuous film layer.

13. The structure of claim 11, wherein the twig portions of the second electrode are structurally respectively annularly extended from the branch portion.

14. The structure of claim 11, wherein the twig portions are different in sizes.

15. The structure of claim 11, further comprising:
a conductor, embedded in the main portion of the second electrode.

16. A method, comprising:
providing a stacked structure including alternately stacked second insulating layers and third insulating layers, wherein a material of the second insulating layer and a material of the third insulating layer are different from each other;
performing a removal process for removing a portion of the second insulating layer and the third insulating layer to form at least one first trench and a plurality of second trenches laterally extending from the first trench;
forming a second conductive layer disposed on an outer surface of the second insulating layer;
forming a dielectric layer disposed on the second conductive layer; and
forming a third conductive layer disposed on the dielectric layer, wherein the third conductive layer and second conductive layer are physically and electrically separated by the dielectric layer.

17. The method of claim 16,
wherein in a top view, an area of a topmost surface of the stacked structure is overlapped and within an area of a bottommost surface of the stacked structure;
wherein the stacked structure is disposed on a substrate, the topmost surface is the surface of the stacked structure furthest away from the substrate, and the bottommost surface is the surface of the stacked structure closest to the substrate.

18. The method of claim 17, further comprising:
forming a fourth insulating layer laterally covering the stacked structure, wherein:
a material of the fourth insulating layer is essentially the same as the material of the second insulating layer.

19. The method of claim 16, further comprising:
forming a first conductive layer disposed on a substrate; and
forming a first insulating layer disposed on the first conductive layer; wherein:
the material of the second insulating layer, the material of the third insulating layer, and a material of the first insulating layer are different from each other
a portion of the first insulating layer is removed by the removal process; and
the second conductive layer is further disposed on a portion of the first conductive layer exposed by the first trench.

20. The method of claim 19, wherein the removal process comprises a first removal process and a second removal process, wherein:
the portion of the first insulating layer, the portion of the second insulating layer, and a portion of the third insulating layer are removed by the first removal process for forming the first trench; and
a remained portion of the third insulating layer are removed by the second removal process for forming the second trenches.
